(19) United States
(12) Patent Application Publication
(10) Pub. No.: US 2014/0182651 A1
(43) Pub. Date: Jul. 3, 2014

(54) INTEGRATED JUNCTION INSULATION FOR PHOTOVOLTAIC MODULE

(71) Applicants: Michael Rogerson, San Jose, CA (US); Jing Tian, Mountain View, CA (US)

(72) Inventors: Michael Rogerson, San Jose, CA (US); Jing Tian, Mountain View, CA (US)

(73) Assignee: Nanosolar, Inc., San Jose, CA (US)

(21) Appl. No.: 13/797,284

(22) Filed: Mar. 12, 2013

Related U.S. Application Data
(60) Provisional application No. 61/746,759, filed on Dec. 28, 2012.

(51) Int. Cl. H01L 31/048

(52) U.S. Cl. CPC H01L 31/0485
USPC 136/244

(57) ABSTRACT

The disclosure relates to apparatus and methods of photovoltaic or solar module design and fabrication. A photovoltaic module includes one or more photovoltaic (PV) cells arranged in an array and sandwiched between a support and a top layer, one or more junction insulation structures laminated and integrated within the PC module between the support and the top layer. The one or more junction insulation structures are configured to protect at least one electrical connections formed between an output wire and a busbar electrically connected to at least one of the one or more PC cells. It is emphasized that this abstract is provided to comply with the rules requiring an abstract that will allow a searcher or other reader to quickly ascertain the subject matter of the technical disclosure. It is submitted with the understanding that it will not be used to interpret or limit the scope or meaning of the claims.

### CLAIM PRIORITY

This application claims the priority benefit of commonly owned, co-pending U.S. Provisional Patent Application No. 61/746,759, to Michael Rogerson et al., filed Dec. 28, 2012, and entitled “INTEGRATED JUNCTION INSULATION FOR PHOTOVOLTAIC MODULE” the entire disclosures of which are incorporated herein by reference.

### FIELD OF THE DISCLOSURE

This invention relates generally to a solar power system. More particularly, it relates to apparatus and methods of photovoltaic or solar module design and fabrication.

### BACKGROUND OF THE INVENTION

Photovoltaic (PV) systems use solar panels to convert sunlight into electricity. Such a system typically includes an array of PV modules, an inverter and interconnection wiring. Each PV module has a number of PV cells electrically connected together, which produce direct current (DC) power that may fluctuate with the sunlight intensity. An inverter is provided to convert the collected power to a certain desired voltages or alternating current (AC). Additionally, each module has a positive and a negative output which are electrically connected in series to a respective common positive and negative bus bar or output wire to produce the desired voltage from the module. In order to protect the connection point between the bus bar and the output connector, a junction box is typically included in a PV module.

It is within this context that aspects of the present disclosure arise.

### BRIEF DESCRIPTION OF THE DRAWINGS

FIGS. 1A and 1B are schematic diagrams of an illustrative PV module with conventional junction box design;

FIG. 2 is a schematic diagram of an illustrative PV module with a junction box of the present disclosure;

FIG. 3 is a schematic diagram depicting portions of an illustrative PV module of the present disclosure;

FIG. 4 is an enlarged schematic diagram of a junction area in an illustrative PV module of the present disclosure;

FIG. 5 is an enlarged schematic diagram of a junction area in an illustrative PV module of the present disclosure; and

FIG. 6 is a cross-sectional view of an illustrative PV module of the present disclosure.

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, the aspects of the present disclosure described below are set forth without any loss of generality to, and without imposing limitations upon, the claims that follow this description.

According to aspects of the present disclosure it is envisioned that PV systems can be used to replace conventional building materials in parts of the building envelope as the roof or skylights as so called building-integrated photovoltaics (BIPV) or building-applied photovoltaics (BAPV). Junction boxes on BIPV/BAPV modules must be installed on the front surface of the module as opposed to the backside. This may require an additional area to mount the junction box and create numerous design issues, such as locating an adequate surface area for adhesion of junction boxes, cutback on protection of exposed bus bars, issues relating to pottant fill and adhesion, and compliance of immersion resistant requirements for junction box.

According to aspects of the present disclosure, a photovoltaic module includes one or more photovoltaic (PV) cells arranged in an array and sandwiched between a support and a top layer, one or more junction insulation structures laminated and integrated within the PC module between the support and the top layer. The one or more junction insulation structures are configured to protect at least one electrical connections formed between an output wire and a busbar electrically connected to at least one of the one or more PC cells.

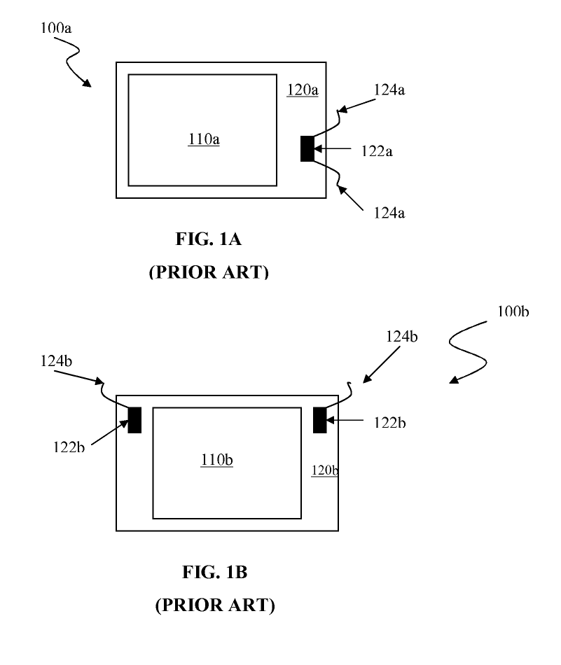

FIGS. 1A and 1B are schematic diagrams of an illustrative PV module with conventional junction box design. Specifically, a PV module 100a (100b) has a PV active area 110a (110b) with a number of PV cells and a peripheral area 120a (120b). A junction box 122a (122b) is placed in the peripheral area 120a (120b) for housing wire connection as shown. With such designs, the active area 110a (110b) in the PV module 100a (100b) is relatively smaller in order to make room for a junction box in the peripheral area 102a (102b).

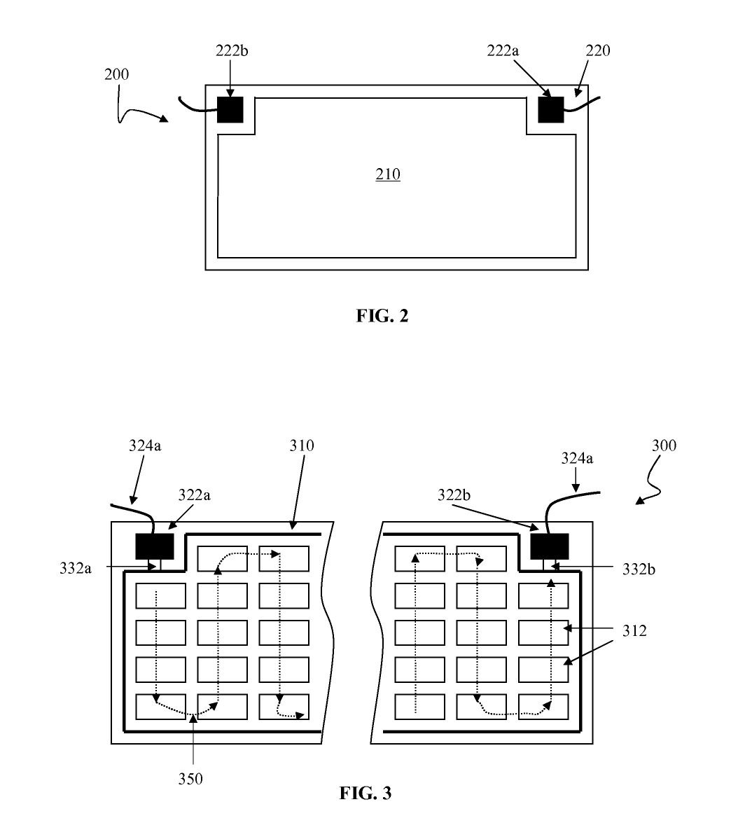

FIG. 2 is schematic diagram of an illustrative PV module with integrated junction insulation in accordance with the present disclosure. In particular, a PV module 200 has a PV active area 210 with an array of PV cells and a peripheral area 220. Junction insulation structures 222a and 222b are placed at the corners of the array of PV cells in the peripheral area 220. By way of example, and not by way of limitation, the junction insulation structures may be junction boxes. However, aspects of the present disclosure are not limited to such implementations. The junction insulation may be implemented by adhesives or lamination of materials over the conductors that form the electrical junction. The junction insulation structures 222a, 222b could include a structure for strain relief but the bulk of the area of the junction structures could also just be plastic if the strain relief requirement is met.

FIG. 3 is a schematic diagram depicting portions of an illustrative PV module in accordance with the present disclosure. A PV module 300 of FIG. 3 includes a number of PV cells 312 in an active area 310 where the cells are arranged in an array. A single cell is removed from a corner of the array and replaced with a junction insulation structure 322a. Another junction insulation structure 322b may be located at another corner of the array. The junction insulation structures 322a and 322b may house a connection between a busbar 332a and wire 324a and between a busbar 332b and wire 324b respectively. The current path 350 from busbar 332a to bus bar 332b may be a serpentine through the cells in a long series connection.

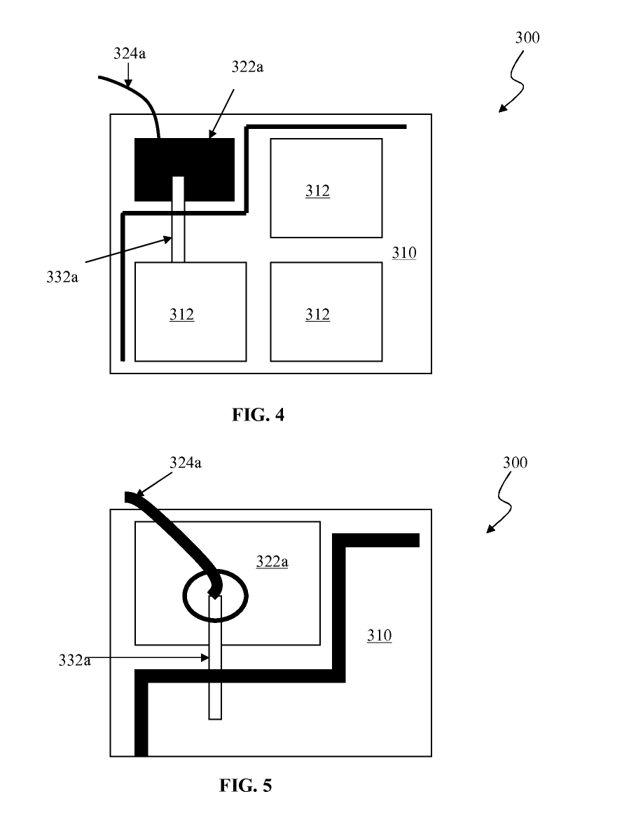

FIGS. 4 and 5 are enlarged views of a junction area in an illustrative PV module of the present disclosure. In particular, the busbar 332a is electrically connected with wire 324a in the junction insulation structure 322a by soldering, welding or a conductive adhesive. The strain relief 360 may be also provided to protect and absorb the external stress that might be on the wire 324a.

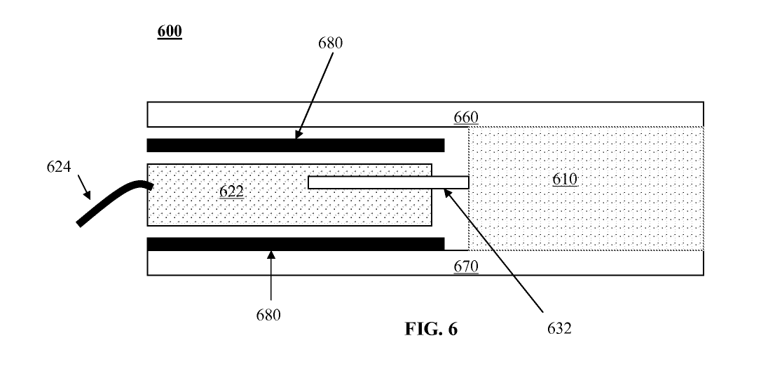

FIG. 6 is a cross-sectional view of an illustrative PV module of the present disclosure. The PV modules include a layer of top sheet 660 and a layer of back sheet 670. The PV cells are sandwiched between the top sheet 660 and the back sheet 670. The top sheet 660 is capable of protecting the PV cells and other electrical components from environment while allowing light energy to pass through. In one example, the top sheet 660 may be a glass layer. The back sheet 670 is also capable of protecting the inner components of a PV module from external stress and acting as an electric insulator. In one example, the back sheet is made of a laminated material, such as 3M™ Scotchshield™ Film 15T or 3M™ Scotchshield™ Film 17T. Other suitable laminated materials include PYE3000® from Coveme Spa of Bologna, Italy, or a thermoplastic polyolefin (TPO) material such as those commonly used in roofing membranes. Materials that may be used for PV cells may include, but not limited to, monocrystalline silicon, polycrystalline silicon, amorphous silicon, cadmium telluride, and copper indium selenide/sulfide. As shown in FIG. 6, a junction insulation structure 622 is integrated and laminated within the module 600. The junction insulation structure 622 may include a strain relief function and a path for a standardized wire 624 and connector to integrate with the module 600. In particular, the junction insulation structure 622 may withstand lamination temperature and pressure conditions. As an example, the junction insulation structure 622 may be made of electrically insulating materials, such as edge seal adhesive materials, lamination materials, ethylene vinyl acetate (EVA), polyvinyl butyral (PVB), or thermoplastic polyolefin TPO). Additionally, the junction insulation structure 622 may be a thin profile in a thickness of about 0.1 to about 10 mm in order not to interfere with the lamination process. Also adhesive films 680 are placed between the junction box 624 and the top sheet 660 and between the junction box 624 and the back sheet 670. As such, no pottant is required as all open spaces will be filled by available adhesive within the module and during the lamination process. Busbar 632 may mount to the junction box 622 with any style of connection such as soldering, welding or by ohmic contact. Additionally, the terminal connector of Busbar 632 may be formed with over/under application of edge seal material. The edge seal material may be a synthetic polymer based sealant with integrated desiccant, such as Helioseal® PVS 101 from Adco, Inc. of Michigan Center, Mich.

While the above is a complete description of the preferred embodiment of the present invention, it is possible to use various alternatives, modifications and equivalents. Any feature described herein, whether preferred or not, may be combined with any other feature described herein, whether preferred or not.

What is claimed is:

1. A photovoltaic (PV) module, comprising:
one or more photovoltaic (PV) cells arranged in an array, wherein the one or more PV cells are sandwiched between a support and a top layer; and
one or more junction insulation structures laminated and integrated within the PV module between the support and the top layer, wherein the one or more junction insulation structures are configured to protect at least one electrical connection formed between an output wire and a busbar electrically connected to at least one of the one or more PC cells.

2. The device of claim 1, wherein the one or more junction insulation structures are located at one or more corners of the array of the one or more PV cells and positioned over the at least one electrical connections.

3. The device of claim 1, wherein each of the one or more junction insulation structure includes a structure configured for strain relief.

4. The device of claim 1, wherein the one or more junction insulation structures are made of electrically insulating materials.

5. The device of claim 1, wherein the one or more junction insulation structures are made of plastic.

6. The device of claim 1, wherein the busbar is electrically connected with the output wire in the junction insulation structure by soldering, welding or a conductive adhesive.

7. The device of claim 1, wherein the one or more junction insulation structures include a structure configured to protect and absorb external stresses on the output wire.

8. The device of claim 1, wherein the top layer is a glass layer.

9. The device of claim 1, wherein the support is made of a laminated material or a thermoplastic polyolefin material.

10. The device of claim 1, wherein the one or more PV cells are made of monocrystalline silicon, polycrystalline silicon, amorphous silicon, cadmium telluride, and copper indium selenide/sulfide.

11. The device of claim 1, wherein the junction insulation structures are in a thickness ranging from about 0.1 millimeters to about 10 millimeters.

12. The device of claim 1, further comprising an adhesive film placed between at least one of the one or more junction insulation structures and the top layer and between at least one of the one or more junction insulation structures and the support.

13. The device of claim 1, wherein the busbar is mounted to at least one of the one or more junction insulation structures by soldering, welding or ohmic contact.
